(19) United States
(12) Patent Application Publication
(10) Pub. No.: US 2025/0365889 A1
(43) Pub. Date: Nov. 27, 2025

(54) CONTROL OF SUB-AMBIENT COOLING OF INTEGRATED CIRCUIT SYSTEMS, APPARATUS AND DEVICES USING PROGRAM WORKLOAD HINTS

(71) Applicant: Advanced Micro Devices, Inc., Santa Clara, CA (US)

(72) Inventors: Yoshifumi NISHI, Austin, TX (US); Christopher Michael HELBERG, Austin, TX (US)

(21) Appl. No.: 18/670,700

(22) Filed: May 21, 2024

(51) Int. Cl. H05K 7/20

(52) U.S. Cl. CPC H05K 7/20209; H05K 7/20154; H05K 7/2039

(57) ABSTRACT

Program workload hints are sent from a processor to a sub-ambient cooling controller at or before the start of the program to enable the sub-ambient cooling device so that required cooling of the processor integrated circuit is anticipated before a significant temperature rise in the processor occurs. Program workload hints are used instead of processor temperature so that thermal lag is reduced, thereby reducing processor temperature rise. In addition, power to the sub-ambient cooling device may be turned off near or at completion of the program to minimize cooling power used. Multiple processors may share sub-ambient cooling device fans during thermal load diversity of the processors running programs at different times.

### TECHNICAL FIELD

Embodiments of the present disclosure generally relate to cooling of integrated circuit systems, apparatus and devices, and in particular, to control of sub-ambient cooling of the integrated circuit systems, apparatus and devices using program workload hints.

### BACKGROUND

Cooling of electronic systems and devices such as, for example but not limited to, computer systems comprising digital processors, data storage; and communications, network and peripheral interfaces; may use sub-ambient cooling devices such as thermo-electric coolers and micro-refrigerators that are capable of cooling the electronic systems and devices to below ambient temperature. However, to avoid damages to internal electronic components due to moisture condensation, these sub-ambient cooling devices need to be power gated so that internal temperatures of the electronic systems and devices stay above dew point. Conventional approaches to control of the sub-ambient cooling devices may be by gating of power thereto based upon temperature using a closed-loop control system. Closed-loop control of power to the sub-ambient cooling devices based solely on temperature has been effective but has an inherent thermal response lag time and suffers from power inefficiencies because it keeps the sub-ambient cooling device running regardless of processor and other electronics utilization loading.

### SUMMARY

In one example of the disclosure, an electronic apparatus includes a digital processor, a cooling device in thermal communications with the digital processor and a cooling device controller electrically coupled to the digital processor and cooling device, wherein the digital processor sends program workload hints to the cooling device controller for determining operation of the cooling device in cooling the digital processor.

In one example of the disclosure, a method for controlling temperature of an electronic apparatus includes cooling a digital processor with a cooling device, and controlling the cooling device with program workload hints from the digital processor.

In one example of the disclosure, a digital processing system on a chip (SoC), includes: A cooling device. A digital processor thermally coupled to the cooling device. A memory coupled to the digital processor. An interposer coupled to the data storage and the digital processor. An integrated circuit package substrate coupled to the interposer. The cooling device is controlled by program workload hints from the digital processor.

In one example of the disclosure, a digital processing system includes: At least one cooling device. At least one digital processor thermally coupled to a respective one of the at least one cooling device. A cooling device controller coupled to the at least one cooling device and the at least one digital processor. The cooling device controller receives program workload hints from the at least one digital processor to control the at least one cooling device associated with the at least one digital processor for cooling thereof.

### BRIEF DESCRIPTION OF THE DRAWINGS

So that the manner in which the above recited features of the present invention can be understood in detail, a more particular description of the invention, briefly summarized above, may be had by reference to examples, some of which are illustrated in the appended drawings. It is to be noted, however, that the appended drawings illustrate only typical examples of this invention and are therefore not to be considered limiting of its scope, for the invention may admit to other equally effective examples.

FIG. 1 illustrates a representative schematic block diagram of a prior art system for cooling a digital processor using a heat sink or sub-ambient cooler, temperature sensor and fan.

FIG. 2 illustrates representative schematic graphs of correlated heat sink temperature, processor power and cooling fan speed representations of the prior art cooling system and digital processor of FIG. 1.

FIG. 3 illustrates representative schematic graphs of correlated cooling device temperature, processor power and cooling device power representations of the prior art cooling system and digital processor of FIG. 1.

FIG. 4 illustrates a schematic block diagram of a system for cooling a digital processor using a sub-ambient temperature cooling device controlled by workload hints, according to an example.

FIG. 5 illustrates representative schematic graphs of the sub-ambient cooling device temperature, digital processor power and cooling device power representations of the cooling system and digital processor of FIG. 5, according to an example.

FIG. 6 illustrates a schematic top view block diagram of a prior art computing system assembly comprising a central processing unit, a graphics processing unit, a sub-ambient cooling device and at least one cooling fan.

FIG. 7 illustrates air flows of the computing system assembly of FIG. 6 when cooling a central processing unit executing an intensive workload by using a sub-ambient temperature cooling device and certain fans, according to an example.

FIG. 8 illustrates air flows of the computing system assembly of FIG. 6 when conventionally cooling a graphics processing unit executing an intensive workload by using a sub-ambient temperature cooling device and certain other fans, according to an example.

FIG. 9 illustrates air flows of the computing system assembly of FIG. 6 when cooling a central processing unit executing an intensive workload by using a sub-ambient temperature cooling device and certain fans, according to an example.

FIG. 10 illustrates air flows of the computing system assembly of FIG. 6 when cooling a graphics processing unit executing an intensive workload by using a sub-ambient temperature cooling device and the certain fans, according to an example.

FIG. 11 illustrates a system on a chip (SoC) assembly using a sub-ambient temperature cooling device controlled by workload hints, according to an example.

To facilitate understanding, identical reference numerals have been used, where possible, to designate identical elements that are common to the figures, and a lower-case letter added where the elements are substantially the same. It is contemplated that elements of one embodiment may be beneficially incorporated in other embodiments.

### DETAILED DESCRIPTION

Various features are described hereinafter with reference to the drawing figures. It should be noted that the drawing figures may or may not be drawn to scale and that the elements of similar structures or functions are represented by like reference numerals throughout the drawing figures. It should be noted that the drawing figures are only intended to facilitate the description of the features of the examples. They are not intended as an exhaustive description of the examples below or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described. Referring now to the drawing figures, the details of examples are representative layouts schematically illustrated. Like elements in the drawing figures will be represented by like numbers, and similar elements will be represented by like numbers with a different lower-case letter suffix.

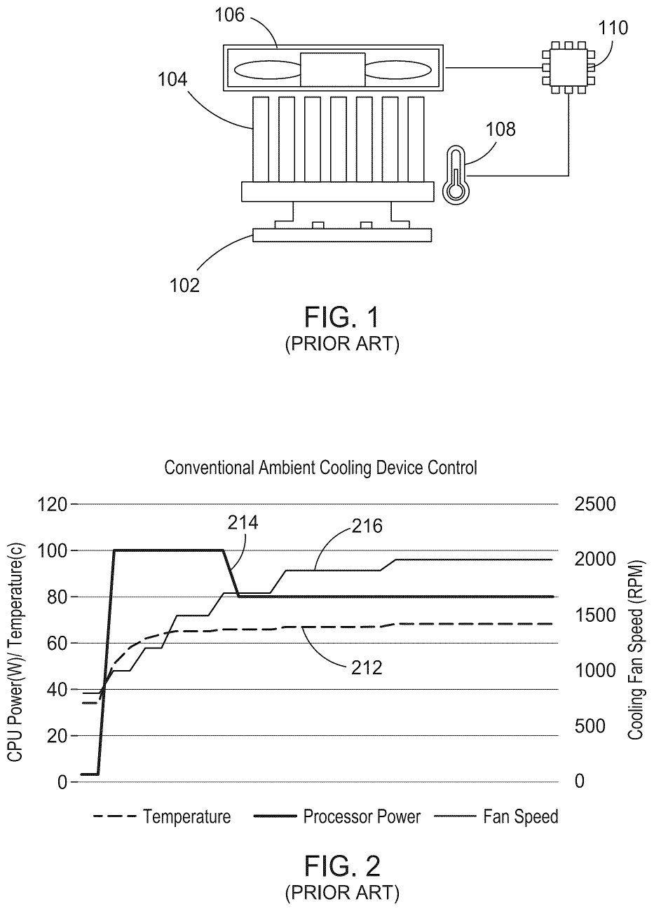

Referring to FIG. 1, depicted is a representative schematic block diagram layout of a prior art system for cooling a digital processor using a cooling device, one or more sensors, and a fan. A digital processor 102 is thermally coupled to a cooling device 104, such as for example but not limited to, a heat sink or sub-ambient cooler. The one or more sensors, shown as sensor 108 in FIG. 1, may be a temperature sensor, a humidity sensor, relative humidity sensor, and/or a dew-point sensor. A power controller 110 is coupled to the sensor 108 and a fan 106. A sub-ambient cooler 104a (not specifically shown but inherent from the description herein) may be, for example but is not limited to, a Peltier module (thermoelectric cooling) or micro-cooler having refrigerant flowing therethrough. The power controller 110 may gate (control) power to the fan 106 and/or the sub-ambient cooler 104a to maintain a certain temperature (temperature set point) as measured by the sensor 108.

FIG. 1 shows conventional closed-loop control of the cooling device 104, wherein the power controller 110 tries to maintain the same temperature of the cooling device 104 by continuously varying power output thereto, essentially decoupling the cooling performance from the digital processor workload. This can be seen in FIGS. 2-4, which shows that the cooling device 104 can operate at different power levels even at the same temperature measured by the sensor 108. Closed-loop control of the cooling device 104 works fine for steady-state processor workloads, however, its slow reacting nature limits performance during bursty processor workloads.

Cooling device 104 performance is proportionally set to maintain a certain temperature of the digital processor 102. For example, higher processor loading generally translates to higher temperature thereof, and there is a direct correlation between the cooling requirements of the digital processor 102 and the cooling device 104 performance necessary to remove the heat generated by the digital processor 102. There is also a time lag in the cooling device's temperature change response time because of the thermal mass of the heat sink or sub-ambient cooler structure resisting changes in temperature thereof.

Referring to FIG. 2, depicted are representative schematic graphs of correlated cooling device temperature, processor power and cooling fan speed representations of the prior art cooling system and digital processor of FIG. 1. Graphs of cooling device temperature 212, processor power 214 and fan speed 216 are shown correlated together over time. The conventional approach of controlling the temperature of the processor 102 may be by gating power to the cooling system, e.g., fan 106 speed control based upon the temperature of the cooling device 104, e.g., heat sink or sub-ambient cooler, is slow to react due to the thermal mass thereof, resulting in a lag in the temperature change. The processor power 214 initially goes to maximum on the graph, then decreases while the cooling device temperature 212 increases and the fan speed 216 maximizes after the processor power 214 has decreased. This is because of the thermal lag in the structure of the cooling device 104.

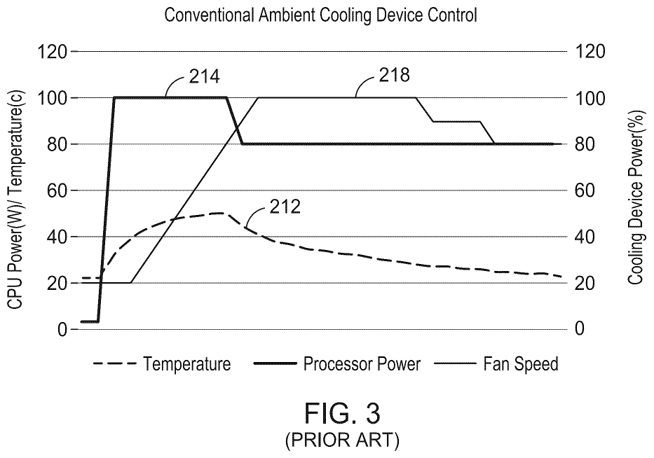

Referring to FIG. 3, depicted are representative schematic graphs of correlated cooling device temperature, processor power and cooling device power representations of the prior art cooling system and digital processor of FIG. 1. Graphs of cooling device temperature 212, processor power 214 and cooling device power 218 are shown correlated together over time. The conventional approach of controlling the temperature of the processor 102 may be by gating power to the cooling device 104, e.g., Peltier module as a sub-ambient cooler, is slow to react due to the thermal mass thereof, resulting in a lag in the temperature change. The processor power 214 initially goes to maximum on the graph, then decreases while the cooling device temperature 212 increases and the cooling device power 218 maximizes after the processor power 214 has started to decrease. This is because of the thermal lag in the structure of the cooling device 104.

The aforementioned prior art cooling solutions as shown in the graphs of FIGS. 2 and 3 and described herein have cooling time lag and increased cooling power requirements based upon thermal lag times of the cooling device structures. The most common solution to improve energy efficiently of sub-ambient cooling devices has been to set higher control target temperatures. However, doing so does not solve slow thermal cooling response to heat generated power transients and results in direct performance loss due to increased average temperature of the digital processor.

Measurement of processor power to supplement temperature-based fan control has been proposed in the past, but does not have sufficient resolution to distinguish the wide range of workloads that today's processors face. For example, the processor power may look identical between a high priority single thread workload and a low priority multi-threaded background task. Supplementing directly with power value also means that the sub-ambient cooling device controller needs to be re-tuned for each thermal design power (TDP) profile, e.g., power traces, of a specific processor, since different processors will have different power traces even on the same workload.

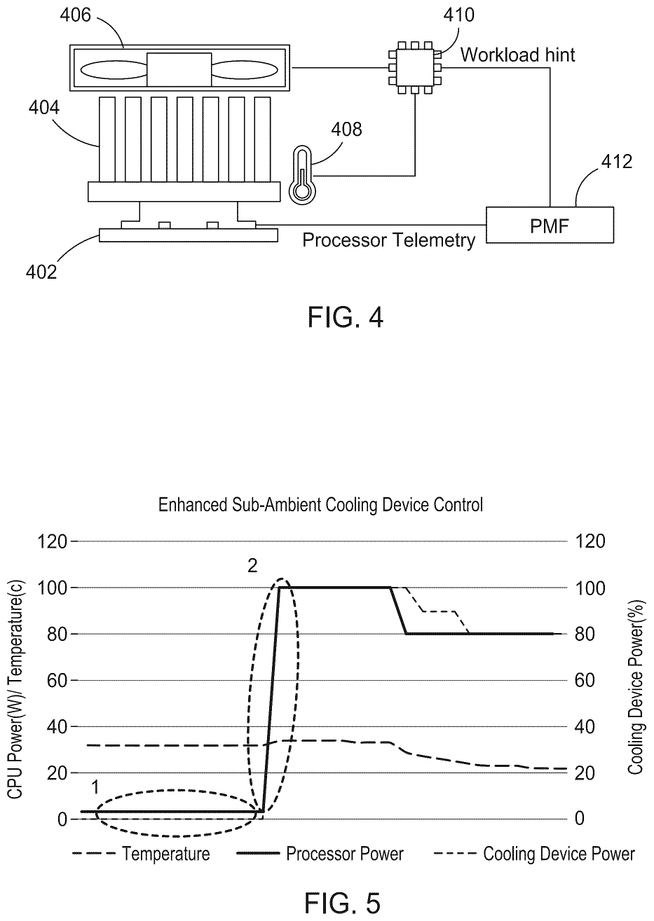

Referring to FIG. 4, depicted is a schematic block diagram of a system for cooling a digital processor using a sub-ambient temperature cooling device controlled by workload hints, according to an example. A processor 402 is thermally coupled to a cooling device 404, such as for example but not limited to, a heat sink or sub-ambient cooler. The cooling device 404 may be, for example but is not limited to, a Peltier module (thermoelectric cooling) or micro-cooler having refrigerant flowing there through. A power controller 410 is coupled to a Platform Management Framework (PMF) driver 412 which may monitor activities on the processor 402 and sends workload hints to the power controller 410 to indicate upcoming cooling needs. These workload hints may be utilized to make the cooling device 404 aware of (activate to cool) future heat loading at or before the start of a program to achieve more efficient and pre-emptive cooling control thereof. By incorporating workload hints, a sub-ambient cooling device 404 may be able to determine if it needs to be on or it can be turned off to conserve power. An additional benefit is decoupling of the sub-ambient cooling device 404 and the processor 402 where possible when not needed to cool the processor 402; meaning, some components of the sub-ambient cooling device 404 may additionally be available for cooling of non-processor components (not shown) when not needed to cool the processor 402. This implementation, according to the teachings of this disclosure, may benefit, for example but is not limited to, small form factor digital system designs. The power controller 410 may modulate the amount of thermal cooling generated by the cooling device 404. Either by varying the fan speed, refrigerate flow or energy into a thermoelectric device.

Possible workload hints may comprise just a few simplified states such as performance, balanced, and silent. This frees the sub-ambient device controller 404 from needing multiple settings based on processor power values, and optimized cooling control may be achieved by using an Auto State Management (ASM) control which may be optimized as a function of a Platform Management Framework (PMF) driver. This frees the power controller 410 from having multiple settings based on power values, and it can always have optimized control simply by updating to a newer PMF driver with optimized ASM control. Also, because PMF is tied deeply into the computing platform, its state decisions may be significantly more advanced and can be expanded to cover future program use cases. Thus, standard generalized cooling device hardware may be used and its cooling operation optimized through software cooling profile tables associated with a program task.

A digital processor may be, for example but is not limited to, at least one or any combination of a microcontroller, a microprocessor, a mixed signal processor, a central processing unit (CPU), a programmable logic array (PLA), an application specific integrated circuit (ASIC), a digital signal processor (DSP), a graphics processing unit (GPU), a field programmable gate array (FPGA), neural processing unit and tensor processing unit.

Referring to FIG. 5, depicted are representative schematic graphs of the sub-ambient cooling device temperature, digital processor power and cooling device power representations of the cooling system and digital processor of FIG. 5, according to an example. By integrating processor workload hints into the cooling device control loop, an open control loop, through the power controller 410, it is now possible, according to the teachings of this disclosure, to more intelligently and proactively manage the sub-ambient cooling device 404. For example, the cooling device 404 can be turned off to save power when the processor indicates that it is in an idle state and active cooling of the processor is not required, as shown in the dashed area 1 (graph portions of processor and cooling device powers) of FIG. 5. Thermal storage and cooling inertia of the cooling device structure may continue to cool the processor 402 even after power is removed from the cooling device 404.

In another example, the cooling device 404 can immediately ramp up to its maximum cooling capabilities when the workload hint indicates that the processor 402 is in an active state, as shown in the dashed area 2 (graph portion of process and cooling device powers) of FIG. 5. This helps to maintain lower overall processor temperature by precooling the cooling device 404 in anticipation of a rapid heat load increase from the digital processor 402. This precooling of the cooling device 404 more effectively maintains a lower operating temperature of the digital processor 402 when a high workload thereof is initiated. E.g., a reserve cooling buffer is created in the cooling device 404. Thus, the cooling device 404 is better able to absorb the instantaneous increased processor heat load, which substantially prevents building up of thermal inertia in the cooling device 404 so that cooling device power may be reduced sooner by beneficially using the thermal inertia of the cooling device 404 to time forward cool the digital processor 402, instead of playing cooling catchup as present cooling technologies are only capable of doing. In a computing system having a plurality of digital processors, a cooling device for each of the plurality of digital processors may be provided and each of the cooling devices may be independently controlled by the cooling device controller based upon program workload hints from one or more of the plurality of digital processors.

If there is a program or processor lockup that may prevent transmission of workload hints from the processor 402, a fail-safe mode may use the sensor 408 in combination with the power controller 410 to control the temperature of the cooling device 404 in a closed loop mode as described for the cooling system shown in FIG. 1. The sensor 408 may also be utilized to measure the sub-ambient cooling device temperature for prevention of condensation in the electronics if the sub-ambient cooling device temperature goes below the dew point of the ambient air. Condensation prevention may further be enhanced with one sensor 108 configured as a relative humidity sensor used in combination with another sensor 108 confiured as a temperature sensor to calculate actual dew point of the surrounding air.

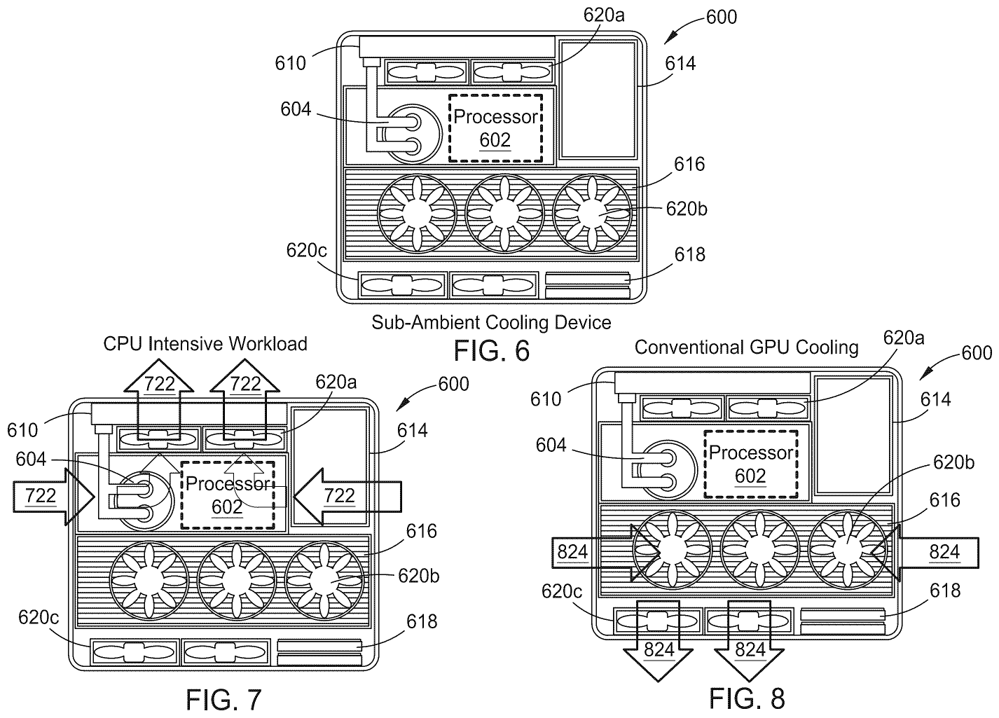

Referring to FIG. 6, depicted is a schematic top view block diagram of a prior art computing system assembly comprising a central processing unit, a graphics processing unit, a sub-ambient cooling device and at least one cooling fan. A computing system assembly, generally represented by the numeral 600, may comprise at least one digital processor 602, a sub-ambient cooling device 604 thermally coupled to the processor 602, a radiator 610 for dissipating heat from the sub-ambient cooling device 604, a power supply 614, a graphics processing unit (GPU) 616, a data storage device 618 and fans 620.

Sub-ambient cooling devices are heat pumps that move heat from a heat generating device; e.g., processor or GPU, to a heat dissipating device; e.g., air, water or refrigerant cooled heat absorption device, e.g., heat sink or radiator. For thermo-electric coolers, this means that heat coupled to it must be dissipated (removed) from it (actively cooled). With processor workload hints, control of heat removal with the thermo-electric cooler can be made independent of the thermo-electric cooler operation and cooling therefrom, e.g., actual processor temperature does not control the actual temperature of the processor, only what program processes it is and will be do. This is indirect cooling device temperature control by workload hints instead of temperature, and is leading not lagging temperature control. Knowledge of the heat generating profiles of processor program workloads enables anticipatory cooling that will be required during execution of a program (workload), earlier removal of power to the cooling device when active powered cooling is no longer required and thermal storage-inertia of the cooling device can be used for the completion of the cooling process. Also, fans 620 of the computing system assembly 600 may be ramped up to generate cooling airflow. For example, when a computing system 600 may be running a graphics processing unit (GPU) intensive workload, the central processing unit(s) (CPU) may not require much cooling from the thermo-electric cooler but the computing system cooling fans can be ramped up to provide cooling air for removal of GPU heat during processing. Traditionally, this was done by a set of another independent fans 620c but this was not a very efficient use of the system's internal volume (extra fans required), especially on Small Form Factor designs.

Referring to FIG. 7, depicted are air flows of the computing system assembly of FIG. 6 when conventionally cooling a central processing unit executing an intensive workload by using a sub-ambient temperature cooling device and certain fans, according to an example. During the start of an intensive workload by a CPU(s) (processor 602), workload hints may be issued to the sub-ambient cooling device 604 that may also turn on specific fans 620a to produce airflows 722 for the processor 602 (CPU).

Referring to FIG. 8, depicted are air flows of the computing system assembly of FIG. 6 when conventionally cooling a graphics processing unit executing an intensive workload by using a sub-ambient temperature cooling device and certain other fans, according to an example. During the start of an intensive workload by a GPU(s) 616, workload hints may be issued to the sub-ambient cooling device 604 that may also turn on specific fans 620c to produce airflows 824 for the GPU 616. GPU fans 620b may be directly controlled by the GPU 616 and run while the GPU 616 executes workloads

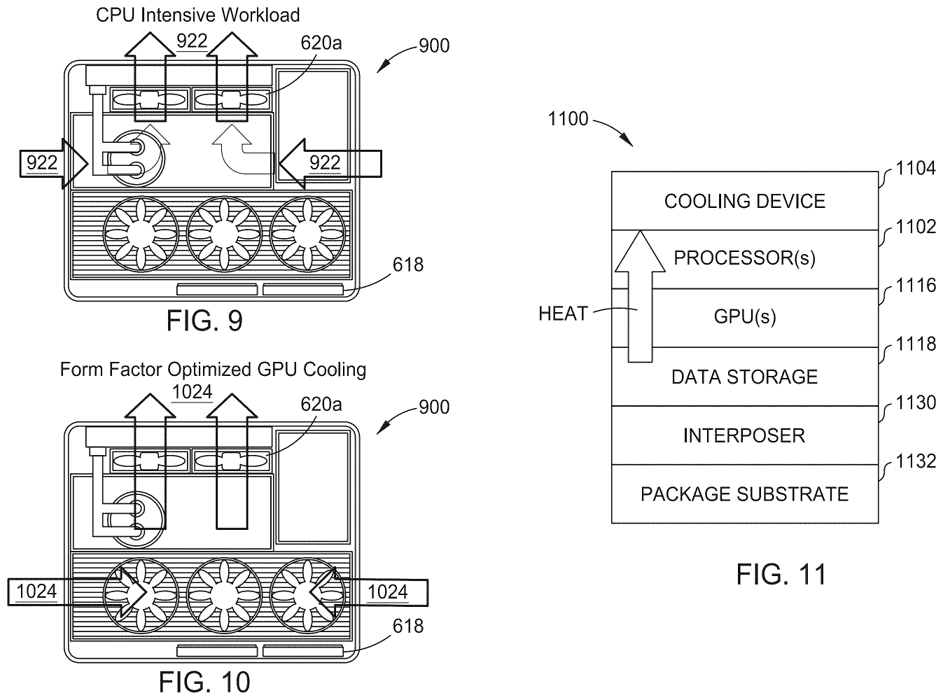

Referring to FIG. 9, depicted are air flows of the computing system assembly of FIG. 6 when cooling a central processing unit executing an intensive workload by using a sub-ambient temperature cooling device and certain fans, according to an example. During the start of an intensive workload by a CPU(s) (processor 602), workload hints may be issued to the sub-ambient cooling device 604 that may also turn on specific fans 620a to produce airflows 922 for the processor 602 (CPU). No other system fans may be required.

Referring to FIG. 10, depicted are air flows of the computing system assembly of FIG. 6 when cooling a graphics processing unit executing an intensive workload by using a sub-ambient temperature cooling device and the certain fans optimized for cooling of the graphics processing unit, according to an example. During the start of an intensive workload by a GPU(s) (processor 616), workload hints may be issued to the sub-ambient cooling device 604 that may also turn on specific fans 620a to produce airflows 1024 for the GPU 616. No other system fans may be required. The computing system assembly 600a has been simplified by eliminating fans 620c. Using workload hints to control the sub-ambient cooling device 604 and at least one cooling fan 620a. By precooling the sub-ambient cooling device 604 during workload operation of the processor 602 and using the thermal inertia thereof, the same sub-ambient cooling device 604 and fans 602 may also cool the GPU 616 during it workload operation.

Referring to FIG. 11, depicted is a system on a chip (SoC) assembly using a sub-ambient temperature cooling device controlled by workload hints, according to an example. A system on a chip (SoC), generally represented by the numeral 1100, may be an integrated circuit (IC) die stack comprising at least one digital processor IC die 1102, at least one graphics processing unit (GPU) IC die 1116, a sub-ambient cooling device 1104 in thermal communication with the processor IC die 1102 and the GPU IC die, at least one data storage IC die 1118, an interposer IC die 1130 and an IC package substrate 1132. The sub-ambient cooling device 1104 may be a thermoelectric cooling device such as Peltier module or micro-cooler having refrigerant flowing therethrough. Through workload hints the sub-ambient cooling device 1104 may ramp up its cooling capacity to anticipate and/or accommodate heat loads generated by the processor 1102, GPU 1116 or both at staggered or substantially the same times.

It is contemplated and within the scope of this disclosure that many different ways of configuring cooling capacity using workload hints as disclosed herein, and one having ordinary skill in the art of IC signal switch circuits and the benefit of this disclosure may design appropriate cooling devices.

As will be appreciated by one skilled in the art and having the benefit of this disclosure, the examples disclosed herein may be embodied as a system, method, apparatus, or computer programmed product. Accordingly, aspects may take the form of an entirely hardware embodiment, an entirely software embodiment (including firmware, resident software, micro-code, etc.) or an example embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

While the foregoing is directed to example embodiments of the present invention, other and further example embodiments of the invention may be devised without departing from the basic scope thereof, and the scope thereof is determined by the claims that follow.

What is claimed:

1. An electronic apparatus, comprising:
a digital processor;
a cooling device in thermal communication with the digital processor; and
a cooling device controller electrically coupled to the digital processor and cooling device, wherein the digital processor is configured to output program workload hints to the cooling device controller, and cooling device controller is configured to control operations of the cooling device in cooling the digital processor based on the program workload hints.

2. The electronic apparatus according to claim 1, wherein the cooling device controller is configured to adjust an amount of cooling of the digital processor by the cooling device based upon a program workload hint associated with a program running in the digital processor.

3. The electronic apparatus according to claim 1, wherein the cooling device controller is configured to adjust power to the cooling device for controlling an amount of cooling of the digital processor by the cooling device based upon a program workload hint associated with a program running in the digital processor.

4. The electronic apparatus according to claim 1, wherein the cooling device is a heat sink in thermal communication with the digital processor and at least one fan configured for removing heat from the heat sink.

5. The electronic apparatus according to claim 1, wherein the cooling device is a thermoelectric cooling Peltier module in thermal communication with the digital processor.

6. The electronic apparatus according to claim 1, wherein the cooling device is operable to cool the digital processor to sub-ambient temperatures.

7. The electronic apparatus according to claim 1, wherein the digital processor is at least two digital processors thermally coupled to the cooling device and electrically coupled to the cooling device controller.

8. The electronic apparatus according to claim 7, wherein the digital processor is selected from the group consisting of any one or a combination of a microcontroller, a microprocessor, a mixed signal processor, a central processing unit (CPU), a programmable logic array (PLA), an application specific integrated circuit (ASIC), a digital signal processor (DSP), a graphics processing unit (GPU), a field programmable gate array (FPGA), neural processing unit and tensor processing unit.

9. The electronic apparatus according to claim 7, wherein the at least two digital processors send program workload hints to the cooling device controller for determining operation of the cooling device in cooling the at least two digital processors.

10. The electronic apparatus according to claim 9, further comprising a cooling device for each of the at least two digital processors and the cooling device controller independently controls each of the cooling devices associated with the at least two digital processors based upon the program workload hints from each of the at least two digital processors.

11. The electronic apparatus according to claim 1, further comprising at least one fan in thermal communication with the cooling device.

12. The electronic apparatus according to claim 11, wherein the at least one fan is controlled by the cooling device controller.

13. The electronic apparatus according to claim 1, further comprising a temperature sensor thermally coupled to the digital processor and electrically coupled to the cooling device controller.

14. The electronic apparatus according to claim 13, wherein the cooling device controller is configured to turn on the cooling device based on a temperature from the temperature sensor exceeding a temperature set point.

15. A method for controlling temperature of an electronic apparatus, comprising:
cooling a digital processor with a cooling device; and
controlling the cooling device based on program workload hints received from the digital processor.

16. The method according to claim 15, further comprising:
enabling the cooling device for maximum cooling of the digital processor when the cooling device is instructed by the program workload hints from the digital processor; and
disabling the cooling device when instructed by the program workload hints from the digital processor.

17. The method according to claim 16, wherein the program workload hints enables the cooling device before a program starts running in the digital processor.

18. The method according to claim 16, wherein the program workload hints disables the cooling device before a program running in the digital processor is finished.

19. A digital processing system on a chip (SoC), comprising:
a cooling device;
a digital processor thermally coupled to the cooling device;
data storage coupled to the digital processor;
an interposer coupled to the data storage and the digital processor; and
an integrated circuit package substrate coupled to the interposer, wherein the cooling device is controlled by program workload hints from the digital processor.

20. The digital processing system of claim 19, further comprising:
a cooling device controller coupled to the cooling device and the digital processor, wherein the cooling device controller is configured to maintain a temperature of the the digital processor above a dew-point based on the program workload hints.
